(19) United States
(12) Patent Application Publication
(10) Pub. No.: US 2026/0239608 A1
(43) Pub. Date: Aug. 13, 2026

(54) DRAM DEVICE AND METHOD OF MANUFACTURING THE SAME

(71) Applicant: NANYA TECHNOLOGY CORPORATION, New Taipei City (TW)

(72) Inventors: Yu Jie Jiang, New Taipei City (TW); Tseng-Fu Lu, New Taipei City (TW); Jhen-Yu Tsai, New Taipei City (TW)

(73) Assignee: NANYA TECHNOLOGY CORPORATION, New Taipei City (TW)

(21) Appl. No.: 19/050,139

(22) Filed: Feb. 11, 2025

(51) Int. Cl. H10B 12/00

(52) U.S. Cl. CPC H10B 12/485; H10B 12/0335; H10B 12/315; H10B 12/482

(57) ABSTRACT

A DRAM device includes at least a substrate, a device isolation structure, bit lines, bit line contacts, spacer structures, and capacitor landing contacts. The device isolation structure is disposed in the substrate to define active areas. The bit lines are disposed on the substrate. The bit line contacts are disposed below the bit lines and connected to a first portion of the active areas, wherein each of the bit line contacts has a necking portion. The spacer structures vertically extend on a sidewall of each of the bit lines and a sidewall of each of the bit line contacts. The capacitor landing contacts are disposed between the bit lines and connected to a second portion of the active areas.

### BACKGROUND

### Technical Field

The disclosure relates to a memory device, and particularly relates to a dynamic random access memory (DRAM) device and a method of manufacturing the same.

### Description of Related Art

With the trend of process shrinkage, bit line structure is designed to become thinner, and the distance between two bit lines is also getting narrower, which causes the parasitic capacitance of bit lines to increase significantly. The parasitic capacitance will directly affect the sensitivity of Sense Margin (ΔV) of DRAM device.

### SUMMARY

The disclosure provides a DRAM device and a method of manufacturing the same for reducing parasitic capacitance.

The DRAM device of the disclosure includes at least a substrate, a device isolation structure, bit lines, bit line contacts, spacer structures, and capacitor landing contacts. The device isolation structure is disposed in the substrate to define active areas. The bit lines are disposed on the substrate. The bit line contacts are disposed below the bit lines and connected to a first portion of the active areas, wherein each of the bit line contacts has a necking portion. The spacer structures vertically extend on a sidewall of each of the bit lines and a sidewall of each of the bit line contacts. The capacitor landing contacts are disposed between the bit lines and connected to a second portion of the active areas.

In an embodiment of the disclosure, each of the bit line contacts has an upper portion on the necking portion and a lower portion below the necking portion, and the upper portion is in direct contact with the bit line.

In an embodiment of the disclosure, the upper portion is larger than the lower portion, or the lower portion is larger than the upper portion.

In an embodiment of the disclosure, a ratio of a minimum diameter of the necking portion to a maximum diameter of the bit line contact is between 0.4 and 0.8.

In an embodiment of the disclosure, a ratio of a height of the bit line contact to a minimum diameter of the necking portion is between 4 and 10.

In an embodiment of the disclosure, the bit line contacts have a bottom below a top of the device isolation structure.

In an embodiment of the disclosure, each of the spacer structures includes an inner spacer, an outer spacer, and a recess filler. The inner spacer is conformally disposed on the sidewall of each of the bit lines and the sidewall of each of the bit line contacts. The outer spacer is disposed on a side of the inner spacer outside each of the bit lines. The recess filler is disposed on the side of the inner spacer under the outer spacer.

In an embodiment of the disclosure, the recess filler has a convex portion with corresponding to the necking portion of each of the bit line contacts.

In an embodiment of the disclosure, the inner spacer is made of a low-k dielectric material, the outer spacer is made of oxide, and the recess filler is a nitride filler.

In an embodiment of the disclosure, each of the capacitor landing contacts has a bottom at a level below the necking portion of each of the bit line contacts.

In an embodiment of the disclosure, each of the bit lines includes a barrier stack and a metal layer disposed on the barrier stack, wherein the barrier stack is disposed on each of the bit line contacts.

In an embodiment of the disclosure, the metal layer is a tungsten layer, and the barrier stack comprises a titanium film, a tungsten nitride film, and a tungsten silicide film stacked in sequence.

The method of manufacturing a DRAM device includes providing a substrate; forming a device isolation structure in the substrate to define active areas; forming primary contacts in a portion of the substrate and a portion of the device isolation structure; forming bit lines on the primary contacts over the substrate; performing a side etching on the primary contacts to form bit line contacts having a necking portion; forming spacer structures vertically extending on a sidewall of each of the bit lines and a sidewall of each of the bit line contacts; and forming capacitor landing contacts between the bit lines.

In another embodiment of the disclosure, the steps of forming the bit lines include depositing a metal layer over the substrate, depositing a cover layer on the metal layer, patterning the cover layer to form a hard mask, and etching the metal layer by using the hard mask as an etching mask.

In another embodiment of the disclosure, after forming the bit lines, the method further includes etching the primary contacts by using the hard mask as an etching mask.

In another embodiment of the disclosure, the steps of forming the spacer structures include forming an inner spacer conformally on the sidewall of each of the bit lines and the sidewall of each of the bit line contacts; filling recesses with a recess filler, wherein the recesses is generated after the side etching at sides of the bit line contacts; and forming an outer spacer on the inner spacer and the recess filler.

In another embodiment of the disclosure, the steps of forming the capacitor landing contacts include forming a sidewall protection structure on the spacer structures to expose a portion of the active areas; forming a polysilicon contacts to connect with the portion of the active areas; and forming landing metal pads over the polysilicon contacts.

Based on the above, according to the DRAM device of the disclosure, the distance between the bit line contact and the capacitor landing contact (including cell contact) may be increased to reduce BL (bit line) to CC (cell contact) parasitic capacitance.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a cross-sectional view of a DRAM device in accordance with some embodiments of the present disclosure.

FIG. 2 illustrates a three-dimensional view of a bit line contact of the DRAM device of FIG. 1.

FIG. 3A through 3N are cross-sectional views of a process for the formation of a DRAM device in accordance with some embodiments of the present disclosure.

### DESCRIPTION OF THE EMBODIMENTS

With reference to the drawings attached, the disclosure will be described by means of the embodiments below. Nevertheless, the disclosure may be embodied in many different forms and should not be construed as limited to the embodiments set forth herein. In the drawings, for the purpose of clarity and specificity, the sizes and the relative sizes of each layer and region may not be illustrated in accurate proportion.

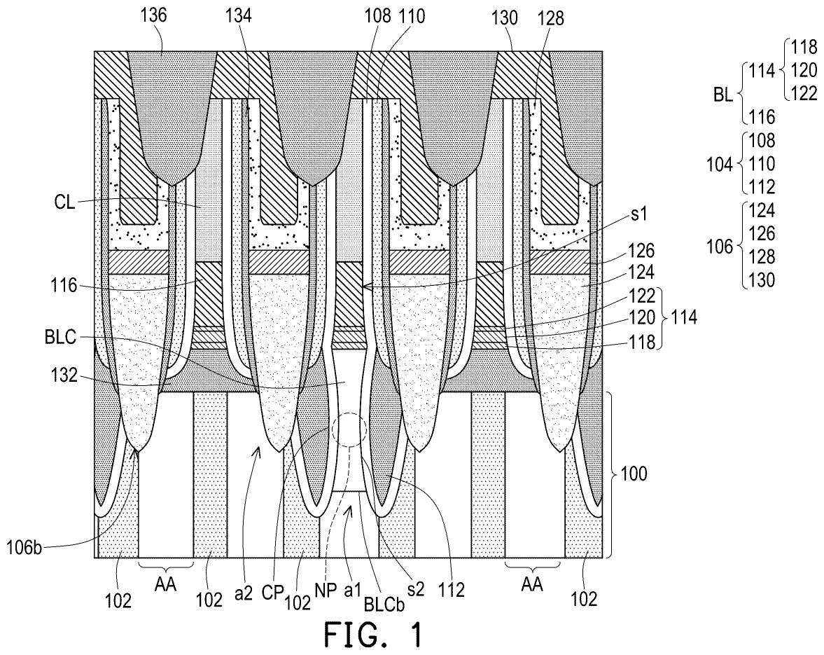

FIG. 1 illustrates a cross-sectional view of a DRAM device in accordance with some embodiments of the present disclosure.

Referring now to FIG. 1, a DRAM device includes at least a substrate 100, a device isolation structure 102, bit lines BL, bit line contacts BLC, spacer structures 104, and capacitor landing contacts 106. The device isolation structure 102 is disposed in the substrate 100 to define active areas AA, wherein the device isolation structure 102 includes, for instance, STI or other suitable structure. The bit lines BL are disposed on the substrate 100. In some embodiments, each of the bit lines BL includes a barrier stack 114 and a metal layer 116 disposed on the barrier stack 114, wherein the barrier stack 114 is disposed on each of the bit line contacts BLC. In one example of the embodiment, the metal layer 116 is a tungsten layer, and the barrier stack 114 comprises a titanium film 118, a tungsten nitride film 120, and a tungsten silicide film 122 stacked in sequence. However, the disclosure is not limited thereto; in some embodiments, the barrier stack 114 may be a bi-layer stack or a multi-layer stack. In addition, a cover layer CL may be optionally disposed over each of the bit lines BL as a mask or a protection layer.

Referring to FIG. 1 again, the bit line contacts BLC are disposed below the bit lines BL and connected to a first portion a1 of the active areas AA, wherein each of the bit line contacts BLC has a necking portion NP. In some embodiments, the bit line contacts BLC have a bottom BLCb below a top of the device isolation structure 102.

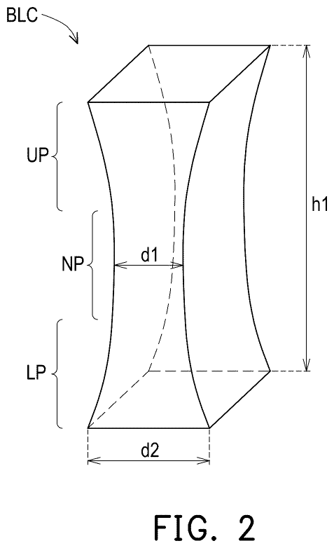

FIG. 2 illustrates a three-dimensional view of a bit line contact BLC of the DRAM device of FIG. 1. As shown in FIG. 2, in some embodiments, one bit line contact BLC has an upper portion UP on the necking portion NP and a lower portion LP below the necking portion NP, and the upper portion UP is in direct contact with the bit line BL in FIG. 1. The upper portion UP may be similar to the lower portion LP in size (e.g. volume, width, height, length, etc.), but it is not limited thereto. In some embodiments, the upper portion UP is larger than the lower portion LP. In some embodiments, the lower portion LP is larger than the upper portion. UP In some embodiments, a ratio of a minimum diameter d1 of the necking portion NP to a maximum diameter d2 of the bit line contact BLC is between 0.4 and 0.8; for example, between 0.5 and 0.75. In some embodiments, a ratio of a height h1 of the bit line contact BLC to a minimum diameter d1 of the necking portion NP is between 4 and 10; for example, between 5 and 8.

Referring back to FIG. 1, the spacer structures 104 vertically extend on a sidewall s1 of each of the bit lines BL and a sidewall s2 of each of the bit line contacts BLC. The spacer structure 104 also vertically extends on the sidewall of the cover layer CL. In some embodiments, each of the spacer structures 104 includes an inner spacer 108, an outer spacer 110, and a recess filler 112. The inner spacer 108 is conformally disposed on the sidewall s1 of each of the bit lines BL and the sidewall s2 of each of the bit line contacts BLC. The outer spacer 110 is disposed on a side of the inner spacer 108 outside each of the bit lines BL. The recess filler 112 is disposed on the side of the inner spacer 108 under the outer spacer 110. In some embodiments, the inner spacer 108 may be disposed between the recess filler 112 and the first portion a1 of the active areas AA. In some embodiments, the recess filler 112 has a convex portion CP with corresponding to the necking portion NP of the bit line contact BLC. In some embodiments, the inner spacer 108 is made of a low-k dielectric material, the outer spacer 110 is made of oxide, and the recess filler 112 is a nitride filler. However, the disclosure is not limited thereto; in some embodiments, the inner spacer 108 is not low-k dielectric material but a silicon nitride layer.

The capacitor landing contacts 106 are disposed between the bit lines BL and connected to a second portion a2 of the active areas AA. In some embodiments, each of the capacitor landing contacts 106 has a bottom 106b at a level below the necking portion NP of the bit line contact BLC. In some other embodiments, each of the capacitor landing contacts 106 has a bottom 106b at a level above the necking portion NP of the bit line contact BLC. In some other embodiments, each of the capacitor landing contacts 106 includes a polysilicon contact 124, a buffer layer 126, a barrier layer 128, and a landing metal pad 130. The polysilicon contact 124 is in direct contact with the second portion a2 of the active areas AA. Due to the necking portion NP, the distance between the bit line contact BLC and the polysilicon contact 124 may be increased to reduce the parasitic capacitance. Accordingly, the sensitivity of Sense Margin (ΔV) of DRAM device may be improved. At the same time, the bottom BLCb of the bit line contact BLC still maintain a larger contact area with the active area AA, and thus the increase of contact resistance may be avoided. The polysilicon contact 124 is isolated with the bit line BL and the bit line contact BLC through the spacer structures 104 and a sidewall protection structure 134 which is between the spacer structures 104 and the capacitor landing contact 106. In some other embodiments, the sidewall protection structure 134 may be omitted. In addition, a nitride layer 132 may be optionally disposed on the substrate 100 as a hard mask for forming the bit line contact BLC. In some embodiments, the buffer layer 126 may include a silicide layer. The barrier layer 128 may include a barrier metal such as titanium nitride on the buffer layer 126. The landing metal pad 130 may include metal such as tungsten. A plurality of pad isolation insulators 136 may be formed to isolate those capacitor landing contacts 106. In some embodiments, capacitor structure (not shown) may be disposed on each of the landing metal pads 130.

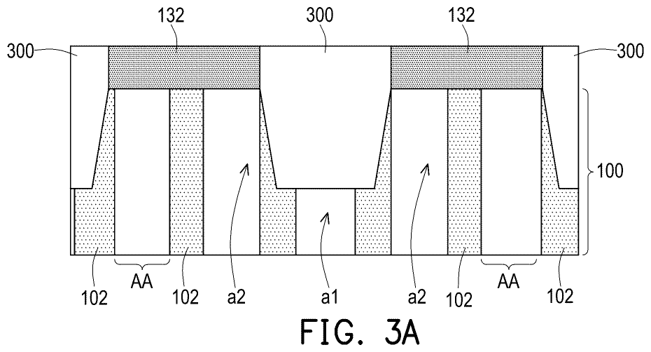

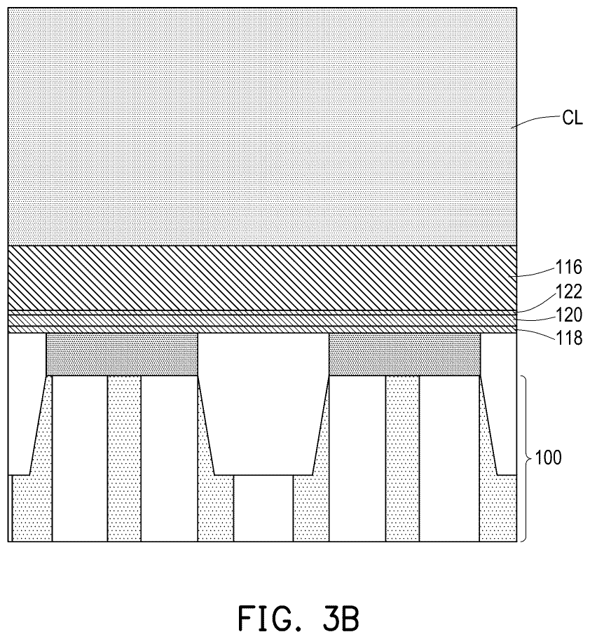

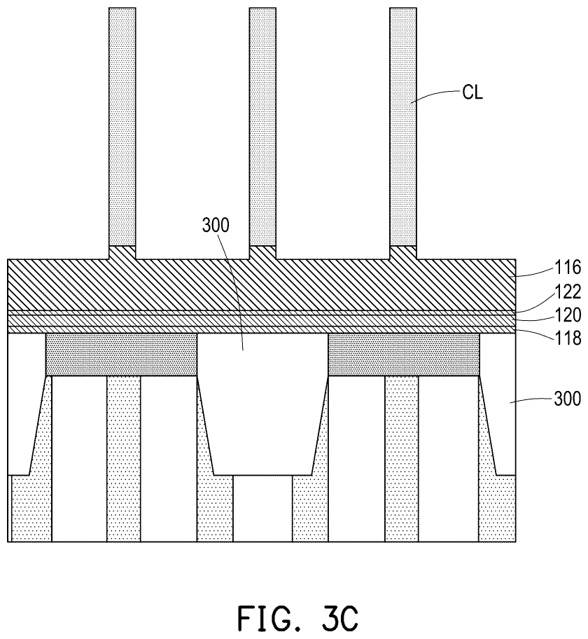

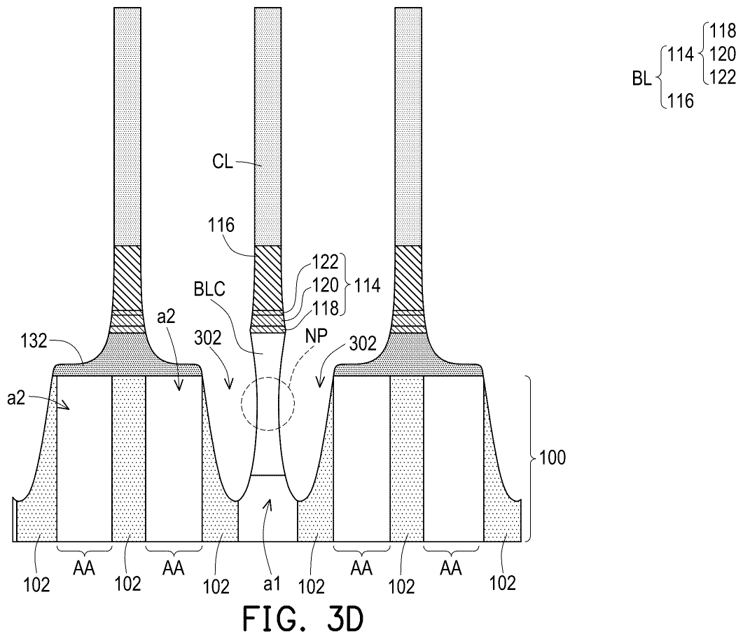

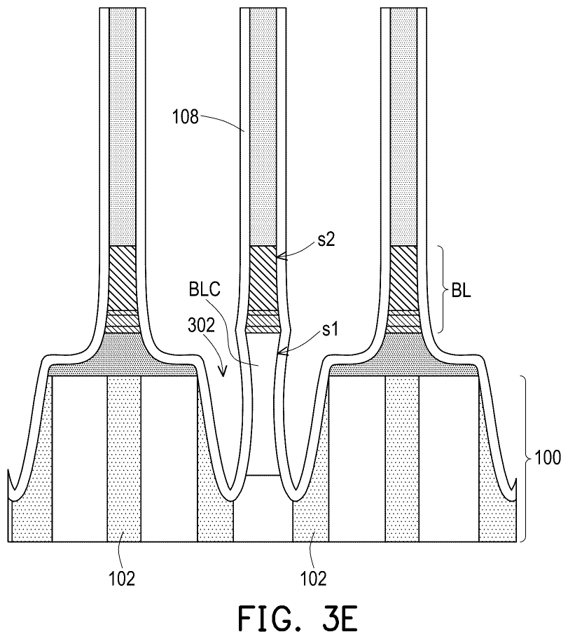

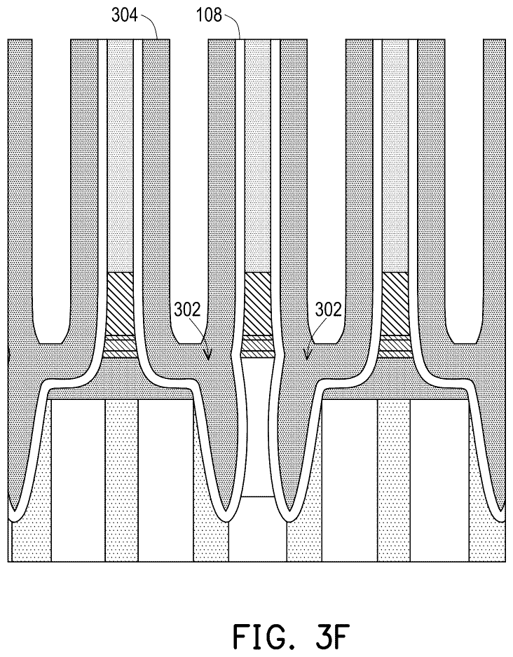

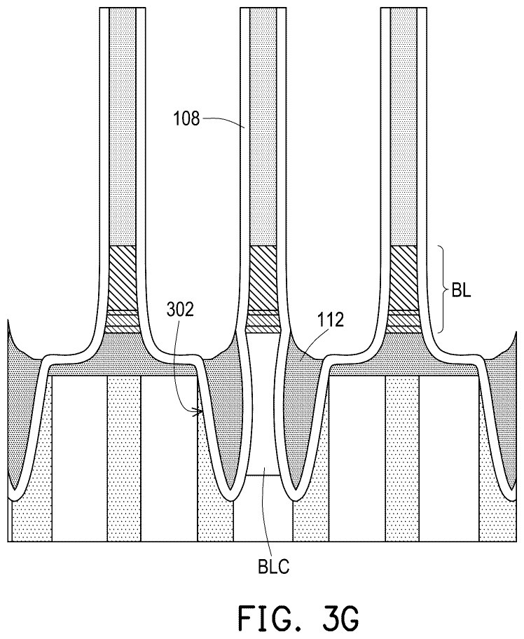

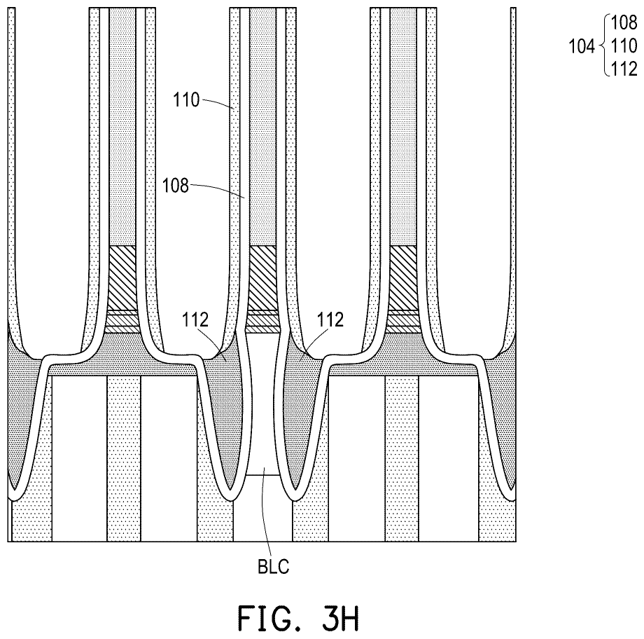

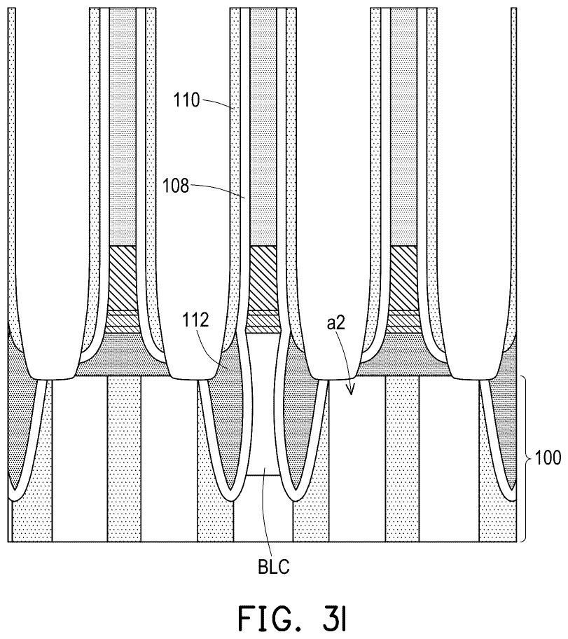

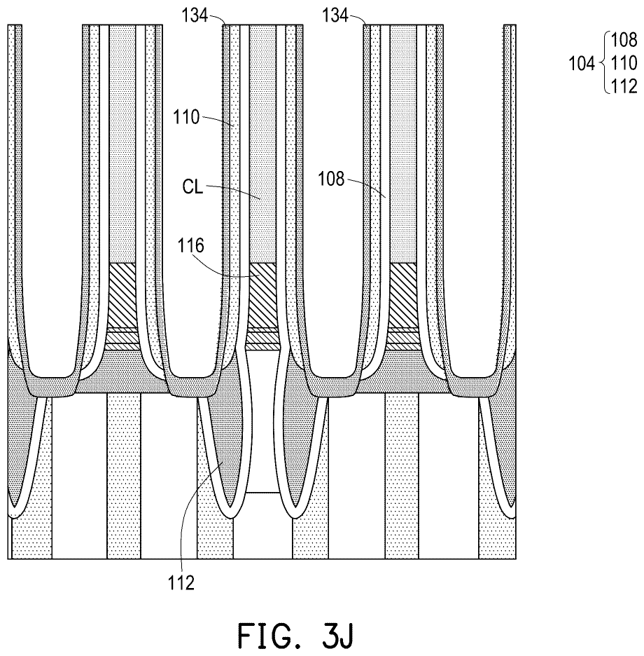

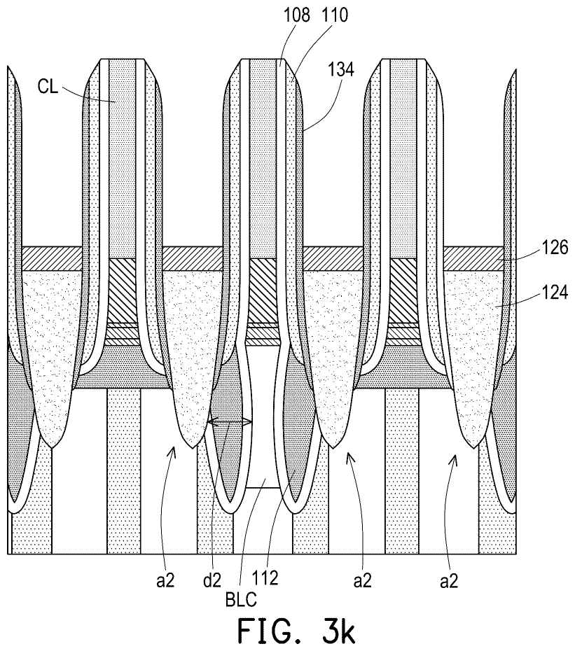

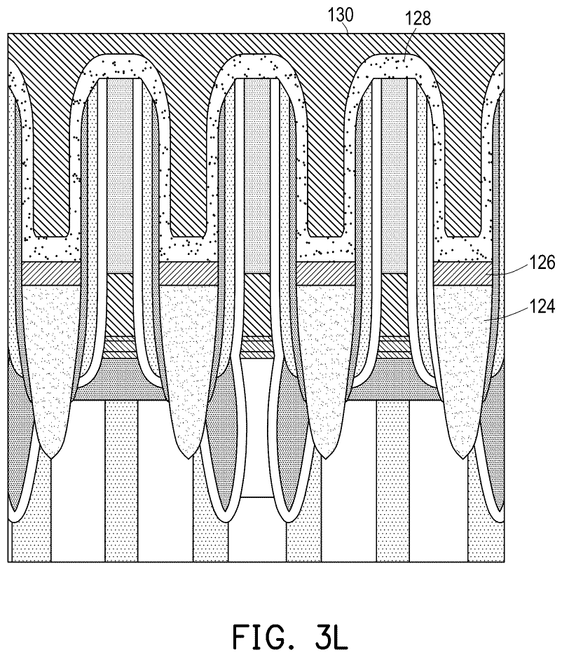

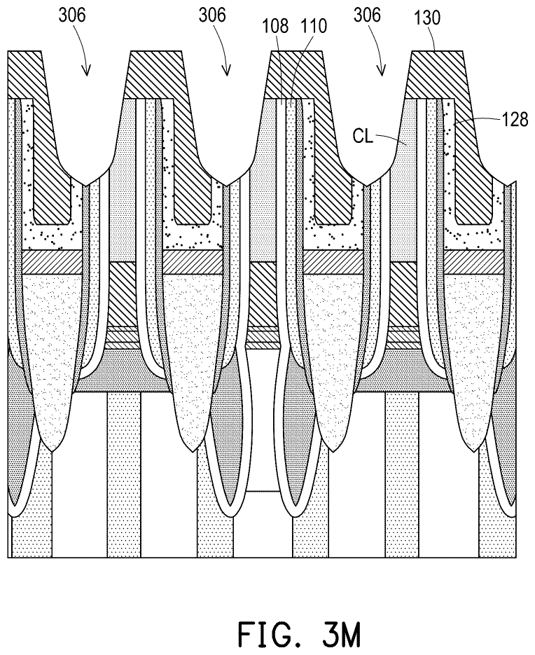

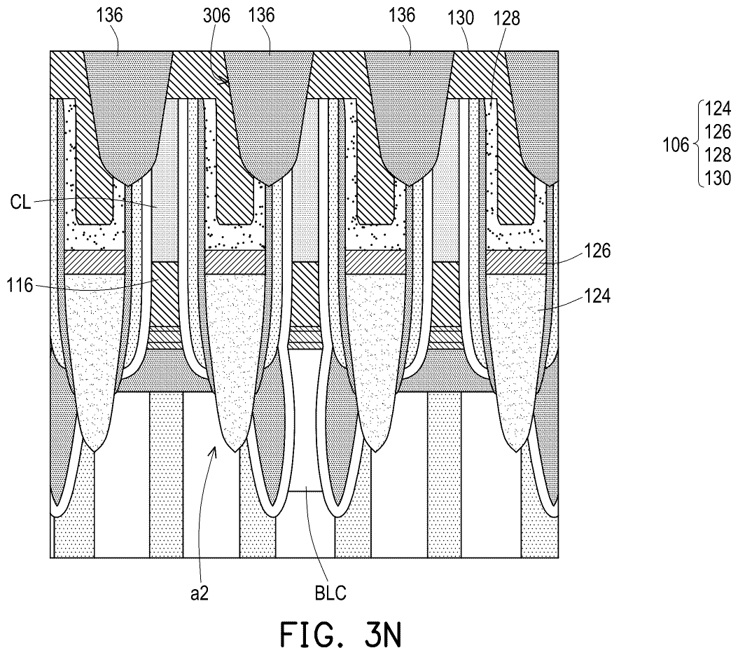

FIG. 3A through 3N are cross-sectional views of a process for the formation of a DRAM device in accordance with some embodiments of the present disclosure, wherein the reference symbols used in FIG. 1 are used to equally represent the same or similar components.

As illustrated in FIG. 3A, a substrate 100 is provided, and a device isolation structure 102 is them formed in the substrate 100 to define active areas AA. The active areas AA include at least a first portion a1 and a second portion a2. In some embodiments, the first portion a1 may be a source region, and the second portion a2 may be drain regions. Primary contacts 300 are formed in a portion of the substrate 100 and a portion of the device isolation structure 102. The method of forming the primary contacts 300 may include forming a nitride layer 132 over the substrate 100, patterning the nitride layer 132 to expose the first portion a1, recessing an upper portion of the first portion a1 by using the patterned nitride layer 132 as a hard mask, and then forming a conductive material in the recesses as the primary contacts 300, wherein the conductive material is, for instance, polysilicon.

With reference to FIG. 3B, in order to form bit lines, the method optionally includes depositing a titanium film 118, a tungsten nitride film 120, and a tungsten silicide film 122 in sequence, and then depositing a metal layer 116 on the tungsten silicide film 122 followed by depositing a cover layer CL on the metal layer 116.

Referring to FIG. 3C, the cover layer CL may be patterned as a hard mask, and then the metal layer 116 is etched by using the hard mask as an etching mask.

Referring to FIG. 3D, the metal layer 116, the tungsten silicide film 122, the tungsten nitride film 120 and the titanium film 118 are continuously etched to form bit lines BL in which the barrier stack 114 is formed. After forming the bit lines BL, the primary contacts may be etched by using the hard mask (i.e. the cover layer CL) as an etching mask. Since the nitride layer 132 has higher etching resistance than the device isolation structure 102 (e.g. silicon oxide), a plurality of recesses 302 are formed in the device isolation structure 102 and a part of the first portion a1. Thereafter, a side etching is performed on the primary contacts to form a bit line contact BLC having a necking portion NP, wherein an etchant of the side etching may be silicon etchant, for instance.

Referring to FIG. 3E, an inner spacer 108 is conformally formed on the sidewall s1 of each of the bit lines BL and the sidewall s2 of each of the bit line contacts BLC. The inner spacer 108 may be a low-k dielectric material such as SiCO, or a silicon nitride layer.

Referring to FIG. 3F, the recesses 302 at sides of the bit line contacts BLC may be filled with a recess filler 304, wherein the filling method for the recesses 302 may be a nitride refill deposition. The recess filler 304 may be also formed on sidewalls of the inner spacer 108.

Referring to FIG. 3G, the recess filler 304 except for the recesses 302 are removed to form recess fillers 112, and the inner spacer 108 at sides of the bit lines BL is exposed.

Referring to FIG. 3H, an outer spacer 110 is formed on the inner spacer 108 and the recess filler 112 to form spacer structures 104.

Referring to FIG. 3I, the inner spacer 108 and the structures thereunder are etched by using the outer spacer 110 as an etching mask until the second portion a2 is exposed.

Referring to FIG. 3J, a sidewall protection structure 134 is optionally formed to conformally on and cover the spacer structures 104. In some other embodiments, the formation of the sidewall protection structure 134 can be omitted.

Referring to FIG. 3K, an anisotropic etching is performed on the sidewall protection structure 134 until the second portion a2 of the active areas is exposed again, and then the second portion a2 is etched by using the sidewall protection structure 134 as an etching mask to deepen the opening for forming polysilicon contacts 124. The polysilicon contacts 124 and the buffer layers 126 are formed, and the polysilicon contact 124 connects with the second portion a2 of the active areas. In FIG. 3K, the tops of the cover layer CL, the inner spacer 108, the outer spacer 110 and the sidewall protection structure 134 may form a round top after above etching steps. The distance d2 between the bit line contact BLC and the polysilicon contact 124 may be increased in comparison with that formed without side etching, and thus the parasitic capacitance may be reduced.

Referring to FIG. 3L, a barrier layer 128 is conformally formed on the buffer layers 126, and a landing metal pad 130 is formed over the polysilicon contacts 124.

Referring to FIG. 3M, openings 306 are formed to separate the landing metal pad 130.

Referring to FIG. 3N, pad isolation insulators 136 are forming in the openings 306 o isolate those capacitor landing contacts 106 between the metal layers 116.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A DRAM device, comprising:
a substrate;
a device isolation structure disposed in the substrate to define a plurality of active areas;
a plurality of bit lines disposed on the substrate;
a plurality of bit line contacts disposed below the bit lines and connected to a first portion of the plurality of active areas, wherein each of the plurality of bit line contacts has a necking portion;
a plurality of spacer structures vertically extending on a sidewall of each of the plurality of bit lines and a sidewall of each of the plurality of bit line contacts; and
a plurality of capacitor landing contacts disposed between the plurality of bit lines and connected to a second portion of the plurality of active areas.

2. The DRAM device of claim 1, wherein each of the bit line contacts has an upper portion on the necking portion and a lower portion below the necking portion, and the upper portion is in direct contact with the bit line.

3. The DRAM device of claim 2, wherein the upper portion is larger than the lower portion.

4. The DRAM device of claim 2, wherein the lower portion is larger than the upper portion.

5. The DRAM device of claim 1, wherein a ratio of a minimum diameter of the necking portion to a maximum diameter of the bit line contact is between 0.4 and 0.8.

6. The DRAM device of claim 1, wherein a ratio of a height of the bit line contact to a minimum diameter of the necking portion is between 4 and 10.

7. The DRAM device of claim 1, wherein the plurality of bit line contacts has a bottom below a top of the device isolation structure.

8. The DRAM device of claim 1, wherein each of the plurality of spacer structures comprises:
an inner spacer conformally disposed on the sidewall of each of the plurality of bit lines and the sidewall of each of the plurality of bit line contacts;
an outer spacer disposed on a side of the inner spacer outside each of the plurality of bit lines; and
a recess filler disposed on the side of the inner spacer under the outer spacer.

9. The DRAM device of claim 8, wherein the recess filler has a convex portion with corresponding to the necking portion of each of the plurality of bit line contacts.

10. The DRAM device of claim 8, wherein the inner spacer is made of a low-k dielectric material, the outer spacer is made of oxide, and the recess filler is a nitride filler.

11. The DRAM device of claim 1, wherein each of the plurality of capacitor landing contacts has a bottom at a level below the necking portion of each of the plurality of bit line contacts.

12. The DRAM device of claim 1, wherein each of the plurality of bit lines comprises:
a barrier stack disposed on each of the plurality of bit line contacts; and
a metal layer disposed on the barrier stack.

13. The DRAM device of claim 12, wherein the metal layer is a tungsten layer, and the barrier stack comprises a titanium film, a tungsten nitride film, and a tungsten silicide film stacked in sequence.

14. A method of manufacturing a DRAM device, comprising:
providing a substrate;
forming a device isolation structure in the substrate to define a plurality of active areas;
forming a plurality of primary contacts in a portion of the substrate and a portion of the device isolation structure;
forming a plurality of bit lines on the plurality of primary contacts over the substrate;
performing a side etching on the plurality of primary contacts to form a plurality of bit line contacts having a necking portion;
forming a plurality of spacer structures vertically extending on a sidewall of each of the plurality of bit lines and a sidewall of each of the plurality of bit line contacts; and
forming a plurality of capacitor landing contacts between the plurality of bit lines.

15. The method of claim 14, wherein steps of forming the plurality of bit lines comprises:
depositing a metal layer over the substrate;
depositing a cover layer on the metal layer;
patterning the cover layer to form a hard mask; and
etching the metal layer by using the hard mask as an etching mask.

16. The method of claim 15, wherein after the steps of forming the plurality of bit lines, further comprising: etching the plurality of primary contacts by using the hard mask as an etching mask.

17. The method of claim 14, wherein steps of forming a plurality of spacer structures comprises:
forming an inner spacer conformally on the sidewall of each of the plurality of bit lines and the sidewall of each of the plurality of bit line contacts;
filling a plurality of recesses with a recess filler, wherein the plurality of recesses is generated after the side etching at sides of the plurality of bit line contacts; and
forming an outer spacer on the inner spacer and the recess filler.

18. The method of claim 14, wherein steps of forming the plurality of capacitor landing contacts comprises:
forming a sidewall protection structure on the plurality of spacer structures to expose a portion of the plurality of active areas;
forming a plurality of polysilicon contacts to connect with the portion of the plurality of active areas; and
forming a plurality of landing metal pads over the plurality of polysilicon contacts.
